(19) United States
(12) Patent Application Publication
(10) Pub. No.: US 2025/0192575 A1
(43) Pub. Date: Jun. 12, 2025

(54) METHOD AND SYSTEM FOR CELL BALANCING AND SECONDARY BATTERIES INCLUDING SAME

(71) Applicant: SAMSUNG SDI CO., LTD., Yongin-si (KR)

(72) Inventor: Youngmin LEE, Yongin-si (KR)

(21) Appl. No.: 18/679,078

(22) Filed: May 30, 2024

(30) Foreign Application Priority Data
Dec. 8, 2023 (KR) 10-2023-0177600

(51) Int. Cl. H02J 7/00; H01M 10/42; H01M 10/44

(52) U.S. Cl. CPC H02J 7/0016; H01M 10/425; H01M 10/441; H02J 7/00714; H01M 2010/4271

(57) ABSTRACT

A system for cell balancing includes: a current measurement circuit to measure a current of a power consumption circuit configured to consume power of a first set of battery cells; a control signal generation circuit to generate a control signal based on the current measured by the current measurement circuit; and a discharge circuit electrically isolated from the control signal generation circuit, and to discharge a second set of battery cells based on the control signal.

### CROSS-REFERENCE TO RELATED APPLICATION

The present application claims priority to and the benefit of Korean Application No. 10-2023-0177600, filed on Dec. 8, 2023, in the Korean Intellectual Property Office, the entire disclosure of which is incorporated by reference herein.

### BACKGROUND

### 1. Field

Aspects of embodiments of the present disclosure relate to a method and system for cell balancing, and secondary batteries including the same.

### 2. Description of the Related Art

Unlike primary batteries that are not designed to be charged/recharged, secondary (or rechargeable) batteries are designed to be discharged and recharged. Low-capacity secondary batteries are used in portable, small electronic devices, such as smart phones, feature phones, notebook computers, digital cameras, and camcorders. Large-capacity secondary batteries are widely used as power sources for driving motors in hybrid vehicles and electric vehicles, and for storing power (e.g., home and/or utility scale power storage). A secondary battery generally includes an electrode assembly composed of a positive electrode and a negative electrode, a case accommodating the electrode assembly, and electrode terminals connected to the electrode assembly.

The above information disclosed in this Background section is for enhancement of understanding of the background of the present disclosure, and therefore, it may contain information that does not constitute prior art.

### SUMMARY

A battery pack may include a battery management module (BMM) that uses the voltage of the battery cells as a power source for voltage and temperature measurements, and a battery management system (BMS) that communicates with the battery management module. With recent changes of shifting communications between the BMM and the BSM to wireless communications, a radio frequency integrated circuit (RFIC) may be used for wireless communications in the BMM. The RFIC may be included in any one of a plurality of battery management integrated circuits (BMICs). In this case, the battery cells used as a power source for the BMIC including the RFIC may be discharged more than those used as power sources for other BMICs. Therefore, an imbalance among the battery cells may occur.

Embodiments of the present disclosure may be directed to systems and methods for cell balancing, and secondary batteries including the same.

The above and other aspects and features of the present disclosure will be more apparent from the following description of some embodiments of the present disclosure.

According to one or more embodiments of the present disclosure, a system for cell balancing includes: a current measurement circuit configured to measure a current of a power consumption circuit configured to consume power of a first set of battery cells; a control signal generation circuit configured to generate a control signal based on the current measured by the current measurement circuit; and a discharge circuit electrically isolated from the control signal generation circuit, and configured to discharge a second set of battery cells based on the control signal.

In an embodiment, the power consumption circuit may include a communication circuit in communication with an external battery management system.

In an embodiment, the current measurement circuit may include a shunt resistor connected to the power consumption circuit to measure a voltage drop associated with the current consumed by the power consumption circuit.

In an embodiment, the control signal generation circuit may include a current amplifier configured to amplify the voltage drop measured by the current measurement circuit.

In an embodiment, the control signal generation circuit may be configured to transmit the control signal to the discharge circuit, while maintaining an electrical isolation from the discharge circuit.

In an embodiment, the control signal generation circuit and the discharge circuit may include an optocoupler configured to transmit and receive the control signal.

According to one or more embodiments of the present disclosure, a secondary battery module includes: a first set of battery cells; a second set of battery cells different from the first set of battery cells; a first battery manager including a power consumption circuit associated with the first set of battery cells; and a second battery manager including a discharge circuit associated with the second set of battery cells. The first battery manager is configured to transmit a control signal associated with a power consumption of the first set of battery cells by the power consumption circuit to the second battery manager, and the second battery manager is configured to discharge the second set of battery cells using the discharge circuit based on the control signal.

In an embodiment, the power consumption circuit may include a communication circuit in communication with an external battery management system.

In an embodiment, the first battery manager may include a shunt resistor connected to the power consumption circuit to measure a voltage drop associated with a current consumed by the power consumption circuit.

In an embodiment, the first battery manager may be configured to generate the control signal by including a current amplifier to amplify the measured voltage drop.

In an embodiment, the first battery manager may be configured to transmit the control signal to the second battery manager, while maintaining an electrical isolation from the second battery manager.

In an embodiment, the second battery manager may include the discharge circuit to discharge an amount of current from the second set of battery cells corresponding to an amount of current consumed by the power consumption circuit.

In an embodiment, the second battery manager may be configured to control a discharge level of the second set of battery cells by the discharge circuit based on an operation mode of at least one of the first battery manager or the second battery manager.

According to one or more embodiments of the present disclosure, a method for cell balancing includes: generating, by a first battery manager, a control signal associated with a power consumption of a first set of battery cells by a power consumption circuit; transmitting, by the first battery manager, the control signal to a second battery manager including a discharge circuit connected to a second set of battery cells; and discharging, by the second battery manager, the second set of battery cells using the discharge circuit based on the control signal.

In an embodiment, the power consumption circuit may include a communication circuit in communication with an external battery management system.

In an embodiment, the generating of the control signal may include measuring, by a shunt resistor connected to the power consumption circuit, a voltage drop associated with a current consumed by the power consumption circuit.

In an embodiment, the generating of the control signal may include: amplifying, by a current amplifier, the voltage drop; and generating, by the first battery manager, the control signal based on the amplified voltage drop.

In an embodiment, the transmitting of the control signal to the second battery manager may include transmitting, by the first battery manager, the control signal to the second battery manager, while maintaining an electrical isolation from the second battery manager.

In an embodiment, the discharging of the second set of battery cells may include discharging, by the second battery manager, an amount of current from the second set of battery cells using the discharge circuit, the amount of current corresponding to an amount of current consumed by the power consumption circuit.

In an embodiment, the discharging of the second set of battery cells may include controlling, by the discharge circuit, a discharge level of the second set of battery cells based on an operation mode of at least one of the first battery manager or the second battery manager.

According to some embodiments of the present disclosure, an imbalance between the battery cells may be prevented or substantially prevented by consuming an amount of power through a discharge circuit of a second cell block that corresponds to an amount of power consumed by a power consumption circuit of a first cell block. Accordingly, the lifespan of the battery cells may be extended.

According to some embodiments of the present disclosure, a cell balancing operation may be performed through an isolated signal between the first battery manager and the second battery manager, which may be electrically isolated from each other. By using the isolation signal, a battery cell balancing system may be simply designed, without the addition of electrical circuits to physically connect the first battery manager and the second battery manager to each other. In other words, the circuits of a battery module including a plurality of cell blocks may not require significant design changes, which may result in lower costs, and cell balancing may be effectively performed at the hardware level.

However, the aspects and features of the present disclosure are not limited to those described above, and the above and other aspects and features will be set forth, in part, in the following detailed description with reference to the drawings, and in part, may be apparent therefrom, or may be learned by practicing one or more of the presented embodiments of the present disclosure.

### BRIEF DESCRIPTION OF DRAWINGS

The above and other aspects and features of the present disclosure will be more clearly understood from the following detailed description of the illustrative, non-limiting embodiments with reference to the accompanying drawings.

FIG. 1 is a schematic block diagram illustrating an example of a secondary battery module including a cell balancing system according to an embodiment of the present disclosure.

FIG. 2 is a schematic diagram illustrating a circuit configuration of a secondary battery module including a cell balancing system according to an embodiment of the present disclosure.

FIG. 3 is a schematic diagram illustrating an example of a method of transmitting an isolation signal generated by one battery manager to a discharge circuit included in another battery manager according to an embodiment of the present disclosure.

FIG. 4 is a circuit diagram illustrating an example of a cell balancing system according to an embodiment of the present disclosure.

FIG. 5 is a diagram illustrating a simulation result of a cell balancing system according to an embodiment of the present disclosure.

FIG. 6 is a flow chart illustrating a method of cell balancing according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein.

References to two compared elements, features, and the like as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

A battery pack according to one or more embodiments of the present disclosure includes at least one battery module, and a pack housing having an accommodation space in which the at least one battery module is accommodated.

The battery module may include a plurality of battery cells and a module housing. The battery cells may be accommodated inside the module housing in a stacked form (e.g., a stacked arrangement or configuration). Each battery cell may have a positive electrode terminal and a negative electrode terminal, and may be a circular type, a prismatic type, or a pouch type according to the shape of the battery. As used in the present specification, a battery cell may also be referred to as a secondary battery, a battery, or a cell.

In the battery pack, one cell stack may constitute one module that is stacked in place of the battery module. The cell stack may be accommodated in an accommodation space of the pack housing, or may be accommodated in an accommodation space partitioned by a frame, a partition wall, and/or the like.

The battery cell may generate a large amount of heat during charging/discharging. The generated heat may be accumulated in the battery cell, thereby accelerating the deterioration of the battery cell. Accordingly, the battery pack may further include a cooling member to remove the generated heat, and thereby, suppress the deterioration of the battery cell. The cooling member may be provided at the bottom of the accommodation space where the battery cell is provided, but the present disclosure is not limited thereto, and the cooling member may be provided at the top or a side depending on the battery pack.

The battery cell may discharge exhaust gas generated inside the battery cell under abnormal operating conditions, also known as thermal runaway or thermal events, to the outside of the battery cell. The battery pack or the battery module may include an exhaust port for discharging the exhaust gas to prevent or reduce damage to the battery pack or battery module by the exhaust gas.

The battery pack may include a battery, and a battery management system (BMS) for managing the battery. The battery management system may include a detection device, a balancing device, and a control device. The battery module may include a plurality of cells that are connected to each other in series and/or parallel. The battery modules may be connected to each other in series and/or in parallel.

The detection device may detect a state of a battery (e.g., a voltage, a current, a temperature, and/or the like) to output state information indicating the state of the battery. The detection device may detect the voltage of each cell constituting the battery or of each battery module. The detection device may detect a current flowing through each battery module constituting the battery module or the battery pack. The detection device may also detect the temperature of a cell and/or a module on at least one point of the battery, and/or an ambient temperature.

The balancing device may perform a balancing operation of a battery module and/or cells constituting the battery module. The control device may receive state information (e.g., a voltage, a current, a temperature, and/or the like) of the battery module from the detection device. The control device may monitor and calculate the state of the battery module (e.g., the voltage, the current, the temperature, a state of charge (SOC), a life span (e.g., a state of health (SOH)), and/or the like) on the basis of the state information received from the detection device. In addition, on the basis of the monitored state information, the control device may perform a control function (e.g., a temperature control, a balancing control, a charge/discharge control, and/or the like), and a protection function (e.g., over-discharge, over-charge, over-current protection, short circuit, a fire extinguishing function, and/or the like). In addition, the control device may perform a wired or wireless communication function with an external device (e.g., a higher level controller or vehicle, a charger, a power conversion system, and/or the like) of the battery pack.

The control device may control charging/discharging operations and a protection operation of the battery. The control device may include a charge/discharge control unit (e.g., a charge/discharge control circuit or controller), a balancing control unit (e.g., a balancing control circuit or controller), and/or a protection unit (e.g., a protection circuit).

The battery management system monitors the battery state, and performs diagnosis and control, communication, and protection functions. The battery management system may calculate the charge/discharge state, may calculate battery life or state of health (SOH), may cut off, as necessary, a battery power (e.g., a relay control), may control thermal management (e.g., cooling, heating, and/or the like), may perform a high-voltage interlock function, and/or may detect and/or calculate insulation and short circuit conditions.

A relay may be a mechanical contactor that is turned on and turned off by the magnetic force of a coil or a semiconductor switch, such as a metal oxide semiconductor field effect transistor (MOSFET).

The relay control has a function of cutting off the power supply from the battery if (e.g., when) a problem occurs in the vehicle and the battery system, and may include one or more relays and pre-charge relays at the positive terminal and the negative terminal, respectively.

In the pre-charge control, a risk of an inrush current may occur in the high-voltage capacitor on the input side of the inverter when the battery load is connected. Thus, to prevent or substantially prevent the inrush current when starting a vehicle, the pre-charge relay may be operated before connecting the main relay, and the pre-charge resistor may be connected.

The high-voltage interlock is a circuit that uses a signal (e.g., a small signal) to detect whether or not all high-voltage parts of the entire vehicle system are connected, and may have a function of forcibly opening a relay if (e.g., when) an opening occurs at even one location on the entire loop.

The balancing device of the battery management system described above performs the balancing operation of the battery module and/or the battery cells at a software level. In comparison, the cell balancing system according to embodiments of the present disclosure may independently perform the balancing operation of the battery cells itself within the battery management module (BMM). In other words, the cell balancing system according to embodiments of the present disclosure may perform the balancing operation of the battery cells at a hardware level.

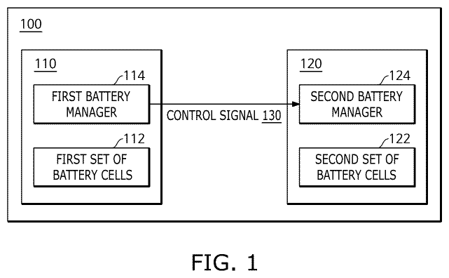

FIG. 1 is a schematic block diagram illustrating an example of a secondary battery module 100 including a cell balancing system according to an embodiment of the present disclosure. In an embodiment, the secondary battery module (e.g., the battery management module) 100 may include a first cell block 110 and a second cell block 120. The secondary battery module 100 may perform a cell balancing operation between the first cell block 110 and the second cell block 120.

In an embodiment, the first cell block 110 may include a first set of battery cells 112, and a first battery manager 114 connected to the first set of battery cells 112. In this case, the first battery manager 114 may include a power consumption circuit connected to the first set of battery cells 112. The power consumption circuit may correspond to, but is not limited to, a communication circuit capable of communicating with an external battery management system (BMS), and may be any suitable component or circuit element that consumes power from the battery cells for communication with the BMS or for battery management purposes.

In an embodiment, the second cell block 120 may include a second set of battery cells 122, and a second battery manager 124 connected to the second set of battery cells 122. In this case, the second battery manager 124 may include a discharge circuit connected to the second set of battery cells 122. The number of battery cells included in the second set of battery cells 122 may be the same as the number of battery cells included in the first set of battery cells 112. For example, the number of battery cells in the first set of battery cells 112 and the number of battery cells in the second set of battery cells 122 may each be 16, but the present disclosure is not limited thereto.

In an embodiment, the first battery manager 114 may generate a control signal 130 associated with a power consumption of the first set of battery cells 112 by the power consumption circuit. In more detail, the control signal 130 may be associated with an amount of power consumed by the power consumption circuit. Further, the first battery manager 114 may transmit the control signal 130 to the second battery manager 124. In this case, the control signal 130 may be transmitted to the second battery manager 124 in an electrically isolated state.

In an embodiment, the second battery manager 124 may operate the discharge circuit in response to receiving the control signal 130. In more detail, the second battery manager 124 may discharge the second set of battery cells 122 using the discharge circuit based on the control signal 130. In this case, the second battery manager 124 may discharge the second set of battery cells 122 through a passive cell balancing, which utilizes the internal resistance of the discharge circuit to consume energy in the battery cells (e.g., the second set of battery cells 122). However, the present disclosure is not limited thereto, and the second battery manager 124 may discharge the second set of battery cells 122, for example, through a power consumption circuit of the second cell block 120.

In an embodiment, the second battery manager 124 may control a discharge level of the second set of battery cells 122 by the discharge circuit based further on the operation mode of at least one of the first battery manager 114 or the second battery manager 124. For example, in a case where the second battery manager 124 is in a sleep mode, the second battery manager 124 may reduce the discharge level of the second set of battery cells 122 through the discharge circuit. In this case, the cell balancing time through the discharge circuit may be increased.

Accordingly, an imbalance between the battery cells may be prevented or substantially prevented by consuming an amount of power through the discharge circuit of the second cell block 120 that corresponds to an amount of power consumed by the power consumption circuit of the first cell block 110. Accordingly, the lifespan of the battery cells may be extended.

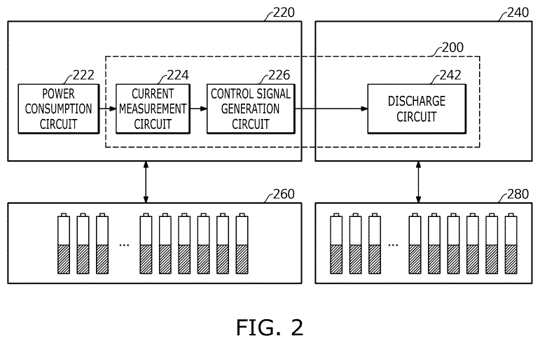

FIG. 2 is a schematic diagram illustrating a circuit configuration of a secondary battery module including a cell balancing system 200 according to an embodiment of the present disclosure. In an embodiment, a first battery manager 220 may include a power consumption circuit 222, a current measurement circuit 224, and a control signal generation circuit 226. The second battery manager 240 may include a discharge circuit 242. In this case, the cell balancing system 200 may include the current measurement circuit 224, the control signal generation circuit 226, and the discharge circuit 242.

In an embodiment, each of the first battery manager 220 and the second battery manager 240 may be connected to a plurality of battery cells. For example, the first battery manager 220 may be connected to a first set of battery cells 260. The second battery manager 240 may be connected to a second set of battery cells 280. The number of battery cells included in each of the first set of battery cells 260 and the second set of battery cells 280 may be the same, but the present disclosure is not limited thereto.

In an embodiment, the power consumption circuit 222 may consume power from the first set of battery cells 260. The power consumption circuit 222 may be, but is not limited to, a communication circuit (e.g., a radio frequency integrated circuit (RFIC)) for communicating with the battery management system. Because the power is consumed from the first set of battery cells 260 by the power consumption circuit 222, an imbalance between the battery cells may occur between the first set of battery cells 260 and the second set of battery cells 280.

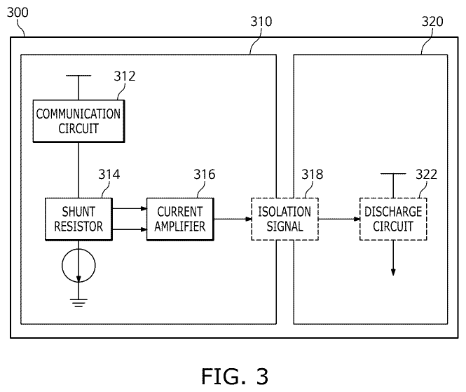

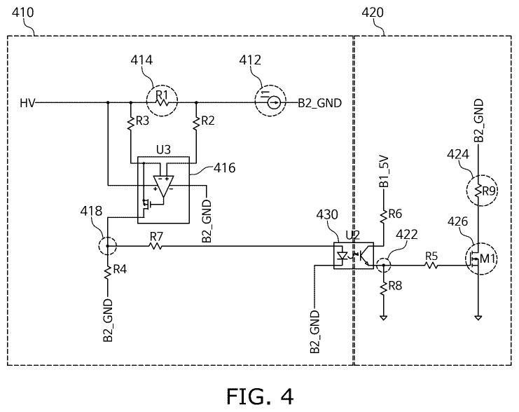

In an embodiment, the current measurement circuit 224 may measure the current consumed by the power consumption circuit 222. Further, the control signal generation circuit 226 may generate a control signal based on the current measured by the current measurement circuit 224. Thereafter, the control signal generation circuit 226 may transmit the control signal to the electrically isolated discharge circuit 242. The discharge circuit 242 may discharge the second set of battery cells 280 based on the control signal, such that the charging energy of the second set of battery cells 280 is adjusted to be equal to or substantially equal to the charging energy of the first set of battery cells 260. In FIG. 2, the current measurement circuit 224 and the control signal generation circuit 226 are illustrated as separate circuits from each other. However, the present disclosure is not limited thereto, and the current measurement circuit 224 and the control signal generation circuit 226 may be integrated together into the same circuit (e.g., into a single circuit). Examples of a method of measuring the current by the current measurement circuit 224 and a method of transmitting the control signal to the discharge circuit 242 by the control signal generation circuit 226 will be described in more detail below with reference to FIGS. 3 and 4.

FIG. 3 is a schematic diagram illustrating an example of a method of transmitting an isolation signal 318 generated by one battery manager to a discharge circuit 322 included in another battery manager according to an embodiment of the present disclosure. In an embodiment, the secondary battery module 300 may include a first battery manager 310 and a second battery manager 320, which may be electrically isolated from each other. The isolation signal 318 associated with the current consumed by the first battery manager 310 may be transmitted to the second battery manager 320, while maintaining the electrical isolation.

In an embodiment, a power consumption circuit may consume power from battery cells connected to the first battery manager 310. For example, the power consumption circuit may be a communication circuit 312. In this case, a voltage drop associated with the current consumed by the communication circuit 312 may be measured using a shunt resistor 314 connected to the communication circuit 312. The shunt resistor 314 may have a small (e.g., a very small) resistance value to measure the current flowing in the circuit. Further, the measured voltage drop may be amplified by a current amplifier 316.

In an embodiment, the isolation signal 318 associated with a voltage value amplified by the current amplifier 316 may be transmitted to the discharge circuit 322. The isolation signal 318 may be associated with an amount of current consumed by the communication circuit 312 in the first battery manager 310. In order to transmit the isolation signal 318 to the second battery manager 320, which is electrically isolated from the first battery manager 310, the isolation signal 318 may be transmitted in an electrically insulated state. For example, the isolation signal 318 may be transmitted from the first battery manager 310 to the second battery manager 320 using an optocoupler or the like, but the present disclosure is not limited thereto.

In an embodiment, the discharge circuit 322 may discharge the battery cells of the second battery manager 320 based on the received isolation signal 318. In this case, the discharge circuit 322 may utilize a resistor contained therein to perform a passive cell balancing operation. A value of the resistor included in the discharge circuit 322 may be determined based on a difference between the current flowing in the circuit of the first battery manager 310 and the current flowing in the circuit of the second battery manager 320.

Accordingly, the cell balancing operation may be performed through an isolated signal (e.g., the isolated signal 318) between the first battery manager 310 and the second battery manager 320, which are electrically isolated from each other. By using the isolation signal, a battery cell balancing system may be simply designed, without the addition of electrical circuits to physically connect the first battery manager and the second battery manager to each other. In other words, the circuits of the battery module including a plurality of cell blocks may not require significant design changes, which may result in lower costs, and cell balancing may be effectively performed at the hardware level.

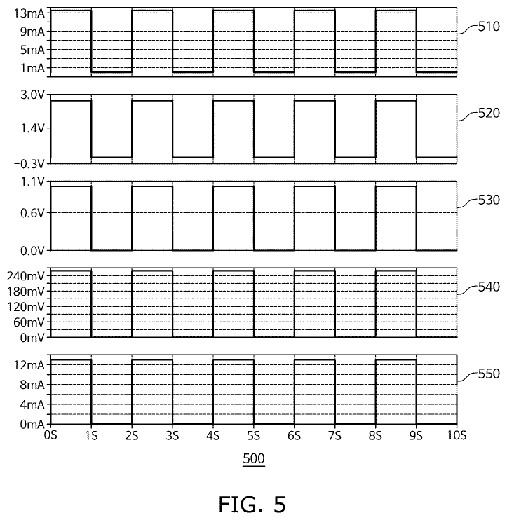

FIG. 4 is a circuit diagram illustrating an example of a cell balancing system according to an embodiment of the present disclosure. FIG. 5 is a diagram illustrating a simulation result 500 of a cell balancing system according to an embodiment of the present disclosure. For example, the simulation result 500 may be an LTspice simulation result 500. In an embodiment, a first circuit of a first cell block 410 may measure the current consumed in a power consuming circuit, and may generate a control signal based thereon. Further, a second circuit of a second cell block 420 may discharge the battery cells based on the control signal.

In an embodiment, a voltage drop associated with the current consumed in the power consuming circuit may be measured through a shunt resistor (R1) 414 connected between a reference power source and a current source 412 in the power consuming circuit. The voltage drop may be amplified by an amplifier (U3) 416. Accordingly, a control signal associated with the amplified voltage drop may be transmitted to the second circuit through a light emitter of an optocoupler (U2) 430.

In an embodiment, the second circuit may include a light receiver of the optocoupler (U2) 430 for receiving the control signal from the first circuit. The light receiver may detect light emitted from the light emitter of the optocoupler (U2) 430, and convert the detected light into an electrical signal. For example, the light emitter of the optocoupler (U2) 430 may include an LED, a laser diode, or the like, and the light receiver of the optocoupler (U2) 430 may include a light sensor, a photodiode, or the like.

In an embodiment, the second circuit may include a switching element (M1) 426 connected to the light receiver and the discharge circuit. The switching element (M1) 426 may control a current flowing in the discharge circuit based on a control signal received from the light receiver. For example, the switching element (M1) 426 may include a field effect transistor (FET), but the present disclosure is not limited thereto. The second circuit may utilize an internal resistor (R9) 424 of the discharge circuit to perform a passive cell balancing operation.

In an embodiment, referring to FIG. 5, a first simulation result 510 indicates a pulse current of the second circuit flowing through the internal resistor (R9) 424 of the discharge circuit. A second simulation result 520 indicates a voltage at an output point (e.g., an output node) 422 of the light receiver after receiving a control signal through the optocoupler (U2) 430. A third simulation result 530 indicates a voltage at an output point (e.g., an output node) 418 of the amplifier (U3) 416. A fourth simulation result 540 indicates a voltage across the shunt resistor (R1) 414, and a fifth simulation result 550 indicates a pulse current of the first circuit flowing in the current source 412. The first simulation result to the fifth simulation result 510 to 550 show that the first circuit exhibits a pulse current with the same period as that of the pulse current of the second circuit. As such, the cell balancing operation of the first cell block 410 and the second cell block 420 may be effectively performed by the cell balancing system according to one or more embodiments of the present disclosure.

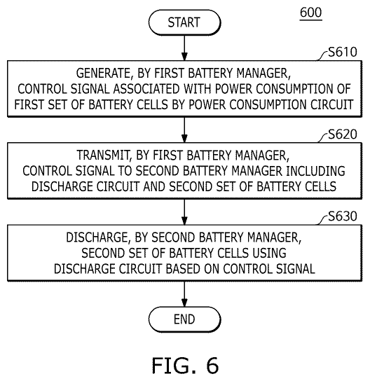

FIG. 6 is a flow chart illustrating a method 600 of cell balancing according to an embodiment of the present disclosure. In an embodiment, the method 600 may be performed by at least one processor. The method 600 may start, and a first battery manager (e.g., a processor of the first battery manager) may generate a control signal associated with a power consumption of a first set of battery cells by a power consumption circuit (S610). The power consumption circuit may correspond to a communication circuit that is in communication with an external battery management system.

In more detail, the processor may measure, using a shunt resistor connected to the power consumption circuit, a voltage drop associated with a current consumed by the power consumption circuit. Further, the processor may amplify, using a current amplifier, the voltage drop. Further, the processor may generate the control signal based on the amplified voltage drop.

Thereafter, the first battery manager (e.g., the processor of the first battery manager) may transmit the control signal to a second battery manager including a discharge circuit connected to a second set of battery cells (S620). In more detail, the processor may transmit the control signal to the second battery manager from the first battery manager, while maintaining electrical isolation from the second battery manager.

Thereafter, the second battery manager (e.g., a processor of the second battery manager) may discharge the second set of battery cells using the discharge circuit based on the control signal (S630). The second battery manager may discharge an amount of current corresponding to an amount of current consumed by the power consumption circuit from the second set of battery cells using the discharge circuit. Further, the processor may control a discharge level of the second set of battery cells by the discharge circuit based further on an operation mode of at least one of the first battery manager or the second battery manager.

The electronic or electric devices and/or any other relevant devices or components according to embodiments of the present disclosure described herein (e.g., the first battery manager, the second battery manager, the power consumption circuit, the power consuming circuit, the current measurement circuit, the control signal generation circuit, the discharge circuit, the communication circuit, the processor, and the like) may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

### DESCRIPTION OF SOME REFERENCE SYMBOLS

100: secondary battery module
110: first cell block
112: first set of battery cells
114: first battery manager
120: second cell block
122: second set of battery cells
124: second battery manager
130: control signal

What is claimed is:

1. A system for cell balancing, comprising:
a current measurement circuit configured to measure a current of a power consumption circuit configured to consume power of a first set of battery cells;
a control signal generation circuit configured to generate a control signal based on the current measured by the current measurement circuit; and
a discharge circuit electrically isolated from the control signal generation circuit, and configured to discharge a second set of battery cells based on the control signal.

2. The system as claimed in claim 1, wherein the power consumption circuit comprises a communication circuit in communication with an external battery management system.

3. The system as claimed in claim 1, wherein the current measurement circuit comprises a shunt resistor connected to the power consumption circuit to measure a voltage drop associated with the current consumed by the power consumption circuit.

4. The system as claimed in claim 3, wherein the control signal generation circuit comprises a current amplifier configured to amplify the voltage drop measured by the current measurement circuit.

5. The system as claimed in claim 1, wherein the control signal generation circuit is configured to transmit the control signal to the discharge circuit, while maintaining an electrical isolation from the discharge circuit.

6. The system as claimed in claim 5, wherein the control signal generation circuit and the discharge circuit comprise an optocoupler configured to transmit and receive the control signal.

7. A secondary battery module comprising:
a first set of battery cells;
a second set of battery cells different from the first set of battery cells;
a first battery manager comprising a power consumption circuit associated with the first set of battery cells; and
a second battery manager comprising a discharge circuit associated with the second set of battery cells,
wherein the first battery manager is configured to transmit a control signal associated with a power consumption of the first set of battery cells by the power consumption circuit to the second battery manager, and
wherein the second battery manager is configured to discharge the second set of battery cells using the discharge circuit based on the control signal.

8. The secondary battery module as claimed in claim 7, wherein the power consumption circuit comprises a communication circuit in communication with an external battery management system.

9. The secondary battery module as claimed in claim 7, wherein the first battery manager comprises a shunt resistor connected to the power consumption circuit to measure a voltage drop associated with a current consumed by the power consumption circuit.

10. The secondary battery module as claimed in claim 9, wherein the first battery manager is configured to generate the control signal by comprising a current amplifier to amplify the measured voltage drop.

11. The secondary battery module as claimed in claim 7, wherein the first battery manager is configured to transmit the control signal to the second battery manager, while maintaining an electrical isolation from the second battery manager.

12. The secondary battery module as claimed in claim 7, wherein the second battery manager comprises the discharge circuit to discharge an amount of current from the second set of battery cells corresponding to an amount of current consumed by the power consumption circuit.

13. The secondary battery module as claimed in claim 7, wherein the second battery manager is configured to control a discharge level of the second set of battery cells by the discharge circuit based on an operation mode of at least one of the first battery manager or the second battery manager.

14. A method for cell balancing, comprising:
generating, by a first battery manager, a control signal associated with a power consumption of a first set of battery cells by a power consumption circuit;
transmitting, by the first battery manager, the control signal to a second battery manager comprising a discharge circuit connected to a second set of battery cells; and
discharging, by the second battery manager, the second set of battery cells using the discharge circuit based on the control signal.

15. The method as claimed in claim 14, wherein the power consumption circuit comprises a communication circuit in communication with an external battery management system.

16. The method as claimed in claim 14, wherein the generating of the control signal comprises measuring, by a shunt resistor connected to the power consumption circuit, a voltage drop associated with a current consumed by the power consumption circuit.

17. The method as claimed in claim 16, wherein the generating of the control signal comprises:
amplifying, by a current amplifier, the voltage drop; and
generating, by the first battery manager, the control signal based on the amplified voltage drop.

18. The method as claimed in claim 14, wherein the transmitting of the control signal to the second battery manager comprises transmitting, by the first battery manager, the control signal to the second battery manager, while maintaining an electrical isolation from the second battery manager.

19. The method as claimed in claim 14, wherein the discharging of the second set of battery cells comprises discharging, by the second battery manager, an amount of current from the second set of battery cells using the discharge circuit, the amount of current corresponding to an amount of current consumed by the power consumption circuit.

20. The method as claimed in claim 14, wherein the discharging of the second set of battery cells comprises controlling, by the discharge circuit, a discharge level of the second set of battery cells based on an operation mode of at least one of the first battery manager or the second battery manager.
